(19) United States
(12) Patent Application Publication
(10) Pub. No.: US 2010/0318306 A1
(43) Pub. Date: Dec. 16, 2010

(54) CAPACITIVE VOLTAGE SENSOR

(75) Inventors: Neil MacLachlan Tierney, London (GB); Benjamin John Pirt, London (GB); Matthew Emmanuel Milton Storkey, Cambridge (GB); Andrew Nicholas Dames, Cambridgeshire (GB); Neil Alexander Rosewell, Cambridgeshire (GB)

Correspondence Address: MCDERMOTT WILL & EMERY LLP, 18191 VON KARMAN AVE., SUITE 500, IRVINE, CA, 92612-7108, US

(73) Assignee: Onzo Limited, London (GB)

(21) Appl. No.: 12/601,527

(22) PCT Filed: May 23, 2008
(86) PCT No.: PCT/GB2008/001783

§ 371 Date: Aug. 27, 2010

(30) Foreign Application Priority Data
May 23, 2007 (GB) 0709893.2

(51) Int. Cl. G01R 21/00; G01R 27/26; G06F 19/00; G01R 1/04; H01M 10/46

(52) U.S. Cl. 702/62; 324/686; 324/156; 320/101; 73/866.3

(57) ABSTRACT

Apparatus for monitoring the voltage of electricity supplied on a cable (121) are described. The apparatus includes a sense electrode housed in an electrically-insulative housing to form a capacitive coupling (127) between the sense electrode and the cable. The housing may be of the clamp-on type. A sense capacitor (128) of known capacitance is included, which is electrically coupled to the sense electrode and a local ground. Suitable voltage measurement circuitry (126) is connected to the sense capacitor and is responsive to voltage produced across the sense capacitor to provide an output signal representative of the voltage on the cable. The measured voltage waveform can be filtered to give the fundamental of the supply voltage, which can eliminate or reduce the effects of changes in capacitance within one cycle. A secondary capacitive (130) coupling can be formed with a related neutral wire (122) to improve stability of the voltage waveform measurement.

### FIELD OF THE INVENTION

This invention relates to apparatus for monitoring the consumption of a resource such as electricity, gas and water. Preferred embodiments of the invention relate more specifically to monitoring the consumption of electricity supplied on a cable, and more particularly to voltage measurement of the electricity supplied on such a cable.

### BACKGROUND

Climate change is one of the greatest challenges facing humanity and energy use in buildings accounts for around 47% of carbon emissions from the UK at present. Efforts to reduce these emissions include technical efficiency improvements through more energy-efficient products, the use of renewable energy, and other large infrastructure and technology products such as micro-generation stations. Efforts are also required to change the patterns of energy use by consumers and it is the interaction between people and technology that makes energy usage a socio-technical issue. Demand can vary by a factor of two or more between identical buildings with the same number of occupants, and this suggests that reducing waste through behavioural efficiency is essential.

The UK government has recently announced the intention to require electricity suppliers upon request to provide home energy monitors to their customers: —This would represent significant capital costs to the utility suppliers, whose objectives are to acquire and retain customers and to increase the average revenue from customers by using existing and new products and services.

The utility suppliers, and in particular the electricity suppliers, recognise three major obstacles to progress in these strategic objectives: a shortage of sources of competitive advantage, a lack of detailed understanding of their customers, and a lack of “touch points”, i.e. ways of interacting with the customers. Opportunities for differentiation revolve mainly around price and, to a much smaller extent, green issues i.e. issues that apparently reduce environmental impact. The utilities have very little information about their customers since the electricity and gas and water meters collect whole house data continuously and are read infrequently. The utilities do not have the opportunity to deliver their brand, i.e. to market their services, in a positive way into the lives of their customers. Their current “touch points”: billing and customer services, have negative connotations.

In a standard energy meter, as often used by utility suppliers, the instantaneous power is derived from measurement of instantaneous current and instantaneous voltage (P=VI). This is then integrated over time to give energy. Both the voltage and current are alternating, e.g., at 50 Hz or 60 Hz, depending on geographical location. Present clamp-on energy monitors measure the current only and assume a fixed voltage amplitude and a fixed phase relationship between current and voltage to estimate the energy usage. Both assumptions lead to inaccuracies in the measured energy.

### SUMMARY

Accordingly, the purpose of the present invention is to provide technical means for improving the acquisition of information on resource consumption by customers, and in the provision of the energy usage information that is likely to be required in order to comply with government regulations; all this in a way in which minimizes costs and environmental impact.

The present invention provides apparatus for monitoring the consumption of electricity supplied on a cable, comprising: an electricity sensor unit having at least one current transformer housed in an electrically-insulative housing clampable over the cable to form an inductive, non-conductive coupling between the or each current transformer and the cable; the sensor unit comprising: a power supply circuit coupled to the current transformer or to one of the current transformers to generate power for the sensor unit; a current measurement circuit powered from the power supply circuit and responsive to current induced in the, or in one of the, current transformer(s) to provide an output signal representative of the current that has flowed on the cable over a period of time; and a data communication circuit powered from the power supply circuit and responsive to the output signal to transmit data representative of the output signal to an external receiver.

From another aspect, the invention also provides apparatus for monitoring the consumption of electricity supplied on a cable, comprising: an electricity sensor unit having at least one current transformer housed in an electrically-insulative housing clampable over the cable to form an inductive, non-conductive coupling between the or each current transformer and the cable; the sensor unit comprising: a power supply circuit coupled to the current transformer or to one of the current transformers to generate power for the sensor unit; a current measurement circuit powered from the power supply circuit and responsive to current induced in the, or in one of the, current transformers) to provide an output signal representative of the current that has flowed on the cable over a period of time; and a data processor and memory circuit powered by the power supply circuit and configured to be responsive to the output signal to process and store data representative of current consumption on the cable over a period of time.

A further aspect of the invention uses a capacitive measurement of the voltage waveform to deduce the phase relationship between the voltage and the measured current in a clamp on energy meter. This removes the more significant assumption leading to a more accurate energy measurement. Embodiments of a capacitive voltage sensor according to the invention use a capacitive divider technique to measure the voltage waveform present on the live wire. The capacitive divider is formed from a gap between the live conductor and a sense electrode, this includes the insulation on the live wire, a sense capacitance of known value and the capacitance of the device reference voltage to local ground.

Whilst the inventions described above are limited to electricity supply, another aspect of the invention provides apparatus for monitoring the consumption of a resource supplied on a conduit, comprising a resource consumption sensor unit connected to the conduit to allow it to measure consumption of the resource; and a data communication circuit arranged to transmit data representative of the resource consumption sensed by the sensor unit.

Preferred embodiments of these inventions are capable of providing the resource supplier, such as the electricity utility company, with a platform of customer knowledge on which it can build customer offerings. It also allows the supplier to comply with likely future requirements for home energy monitors.

Preferred embodiments of the invention are capable of supply in a modular fashion as a family of products rather than a single device, allowing the system to be expanded further and for it to be tailored to particular needs.

Further preferred embodiments of the electricity monitoring apparatus maybe fitted by clam-ping in a -single process without the need-for maintenance there are no batteries to be changed, and data on consumption can be stored for example for up to five years in a secure fashion.

By integrating the computer memory with the sell powered electricity sensor or other resource sensor, the sensor unit may be placed adjacent an existing electricity meter in a safe part of the customer's house, for example, minimizing risk to the computer memory from impact or other influence. There is no need for any cabling between the memory and the transformer, in the preferred embodiment, which would introduce risks of damage.

The clamp for the current transformer or transformers in the preferred embodiment can be made to fit universally, so that a single configuration of clamp should be sufficient to meet all needs, reducing manufacturing costs substantially.

The provision of detailed consumption information including energy savings related to cost means that the customer is more likely to be informed, educated and even entertained. The provision of a public display of energy savings achieved by a particular customer is likely to incentivise that customer to make the savings by changing his consumption habits. For example, the effect of changing electricity consumption in just one appliance can be demonstrated. Further, the displays offer the supplier the opportunity of displaying its brand and the ways it can differentiate its services from its competitors.

The customer relationship management application in the computer network of the preferred embodiment allows the utilities to build customer offerings, for example by providing high value activities that will address their strategic and tactical challenges: strategic customer targeting, tariff design, tactical customer targeting, bill estimation and identifying new sources of revenue.

In preferred embodiments, the data processing within the network is arranged to allow the customer to tailor an energy saving programme to himself, and to set his own targets for-energy savings. This further incentivises the customer to improve energy efficiency for the sake of reducing costs and reducing environmental impact.

### BRIEF DESCRIPTION OF THE DRAWINGS

In order that the invention may be better understood, preferred embodiments will now be described, by way of example only, with reference to the accompanying diagrammatic drawings in which:

FIG. 1 is a schematic diagram of the overall system embodying the invention for monitoring resource consumption of one location such as a house;

FIG. 2 is a schematic diagram of an electricity sensor un t embodying the invention;

FIG. 3 is a schematic diagram of a user display unit for use in the system of FIG. 1;

FIG. 4 is a schematic diagram of the data return path shown in FIG. 1;

FIG. 5 is a schematic diagram of an electricity appliance sensor unit for use with the system shown in FIG. 1;

FIG. 6 is a schematic diagram of a public window display unit for use with the system shown in FIG. 1;

FIG. 7 is a schematic circuit diagram of one example of the sensor unit of FIG. 2;

FIGS. 8, 9 and 10 show alternative examples to that shown in FIG. 7, using a single current transformer instead of two current transformers; and

FIG. 11 is a schematic circuit diagram of a further alternative example which includes a metered battery charger.

FIG. 12 is a schematic circuit diagram of an embodiment of a capacitive voltage sensor according to the present invention.

FIG. 13 is a schematic circuit diagram of a further embodiment of a capacitive voltage sensor in accordance with present invention.

While certain embodiments are depicted in the drawings, the embodiments depicted are illustrative and variations of those shown, as well as other embodiments described herein, may be envisioned and practiced within the scope of the present disclosure.

### DETAILED DESCRIPTION

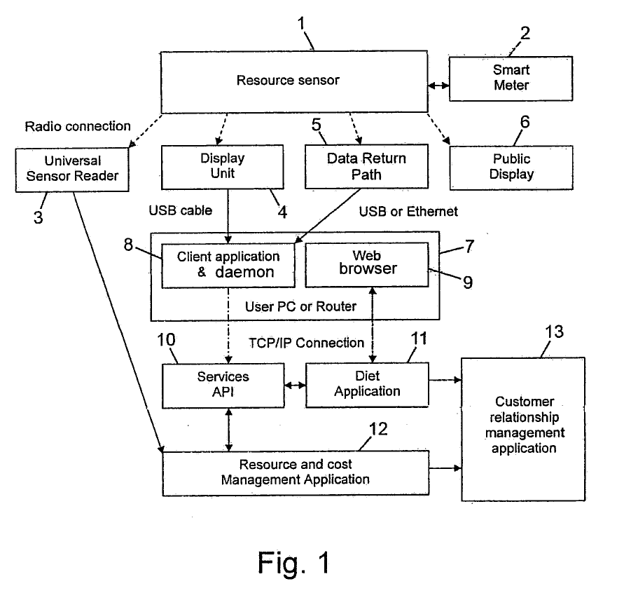

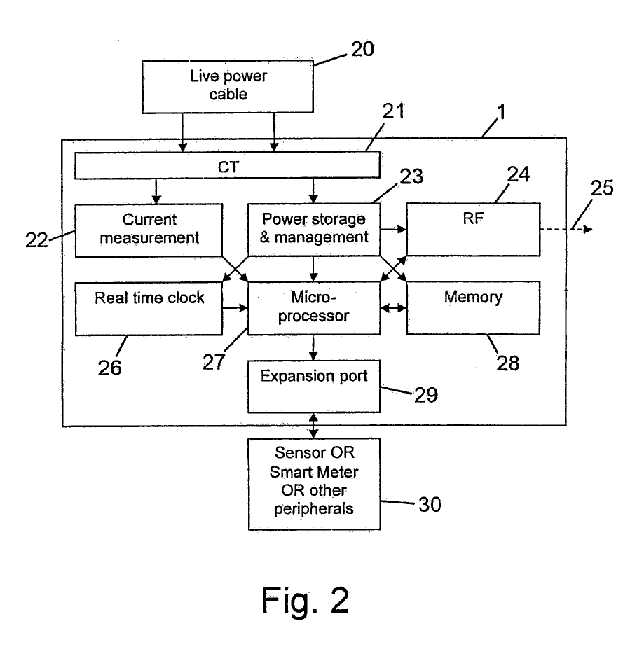

Apparatus for monitoring the consumption of a resource, and embodying the present invention, is shown in FIG. 1. The resource may be electricity, gas or water, supplied to a domestic consumer or to a business consumer through a conventional meter for recording consumption. It may be micro-generated electricity or fuel. Each resource is supplied through a conduit such as a cable or pipe with the meter in series. In some cases, however, the resource may be supplied directly to an appliance. In the preferred embodiment of the invention, and as described further with reference to FIGS. 2 to 11, the resource is electricity supplied on a cable.

The resource sensor 1 responds to the flow of the resource along the conduit, such as the electrical current along the cable, to provide outputs indicative of the resource consumption to a universal sensor reader 3, a display unit 4, a data return path 5 connected to a computer network 7 to 13, and a public display or public window display 6. The resource sensor 1 communicates interactively with a smart meter 2 which is in series with the conduit and which has a communications facility.

The universal sensor reader 3 is a wireless, portable, rugged, hand-held device as used by energy supplier businesses to read sensors periodically. As shown in FIG. 1, the universal sensor reader 3 receives a radio output from the resource sensor 1, indicative of the resource consumption over a period of time; it then communicates this data, either immediately or at a convenient time in the future, to a resource and cost management application 12 on the computer network.

The computer network includes a user PC (Personal Computer) or router 7 (which may be wireless) which comprises a client application program 8 and a daemon program 8 running in the background, together with a web browser 9, connected by way of a TCP/IP connection to the Internet. This enables communication over the Internet to the remainder of the computer network, which comprises a services API 10 intercommunicating with a diet application 11 and with the resource and cost management application 12. Both the diet application and the resource and cost management application 12 provide outputs to a customer relationship management application 13 intended for third parties such as the energy supplier businesses.

The diet application 11 controls the way in which the resource consumption is monitored and controlled in accordance with customer requirements. It interfaces with the user PC or router 7 through the services API 10 which is the Application Programming Interface. By way of example, the customer enters data interactively on his user PC 7 to indicate the nature of the energy savings he wishes to make, and to enter a schedule or program of ways of achieving this, by changing the pattern of energy consumption in each major appliance in his house. This is recorded in the diet application 111 which interacts with the customer relationship management application 13. The resource and cost management application receives data relating to the tariff from the customer relationship management application 13, and receives resource consumption data from the user PC or router 7 through the network. It provides the supplier with data on the pattern of consumption over a period of time, and it is capable of transmitting data back to the domestic system 1, 5, 7 for controlling consumption. Using an individual appliance sensor 70 shown in FIG. 5 and described in greater detail below, with a data link 75 to the data return path 5 of FIG. 1, it is possible to issue commands to each appliance to control its program of consumption. For example, heaters could be controlled to switch off for a period during the night. In a regional blackout or brownout, where there is a general limitation on the electricity grid, inessential appliances can be temporarily switched off or their rate of consumption reduced, using this control system.

An example of the resource sensor in the form of an electricity sensor unit 1 is shown in FIG. 2. The sensor unit 1 has an electrically-insulative housing containing preferably just one, but optionally two current transformers (CT) 21, examples of which will be described in more detail below with reference to FIGS. 7 to 11. Each CT 21 is permanently clamped around the live power cable 20 for mains electricity, normally in the vicinity of the electricity meter which is typically protected in a cupboard. Thus the sensor unit 1 is supported entirely by the cable. The sensor unit 1 has a wireless radio link 25 to other parts of the system which rely on the electricity sensor for data.

The housing of the sensor unit 1 further comprises current measurement circuitry 22 and power storage and management circuitry 23 both responsive to induced current in the CT 21. The power storage and management circuitry 23 obtains power from the live power cable 20 in a parasitic fashion through the inductive coupling. It includes electricity storage, typically a rechargeable battery, which would not normally require replacing for at least 5 years.

A microprocessor 27 at the heart of the sensor unit 1 has a memory unit 28 safely stored within the housing of the sensor unit 1, and it receives data from a real time clock 26 indicative of the current time. The microprocessor 27 has an expansion port 29 which interfaces with an external sensor or smart meter or any other peripherals 30. However, in some embodiments the data links with the sensor, meter and any other peripherals could be wireless, so the expansion port may be different or may be unnecessary.

The current measurement circuitry 22 integrates the current from the current transformer 21 to provide an output signal indicative of current flowing in the live power cable 20, and this output signal is fed to the microprocessor 27 and stored in the memory 28. The memory 28 is arranged to store current consumption data for a large period of time, and is protected from interference or tampering so that it cannot be confused with data for other consumers. Typically, the memory 28 is arranged to provide high resolution data with samples at 5 second intervals over a period of 90 days; and low resolution data, with samples at 15 minute intervals, over a period of 5 years, as an archive. This dual formatting approach provides the consumer and the supplier with appropriate data whilst minimising requirements on storage and transmission bandwidth. The high resolution data is used for recent historical analysis of energy use for display on the display unit and/or on the PC. The low resolution data is used over a period typically longer than 3 months for historical analysis of resource use.

By locating the computer memory at the point at which current is sensed, this reduces the likelihood of failure through transmission over a cable or a wireless link.

The use of induction as a source of power for the sensor unit is reliable and provides a continuous power source. It is used together with a rechargeable battery which provides primary power.

The sensor unit 1, which is the primary point of storage of data, has the minimum possible risk of being lost or damaged, for example through impact, by being placed in the meter cupboard. This is achieved by separating the sensor unit 1 from the user display unit 4.

By providing continuous background logging, regardless of any input from the customer, the data are reliably recorded for reading periodically by the supplier, whether through the network or by means of the universal sensor reader 3.

Data may be stored in the memory 28 using two different strategies depending upon the mode of use: a record at regular intervals, and/or a record whenever there is a change.

To provide the highest security against tampering or data loss, encryption is used to protect the data when it is transmitted. Encryption programs are changeable over time with software updates.

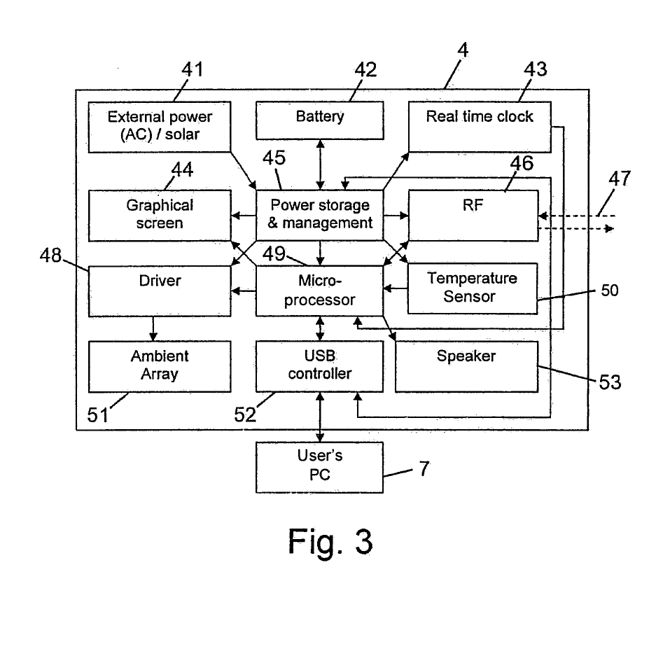

The user display unit 4 is shown in greater detail in FIG. 3. This is a separate unit from the sensor unit 1, and it is normally placed in a convenient location within the home so that it may be read easily by the customer and it may communicate easily with the customer's PC or router 7 through the data return path 5. A microprocessor 49 receives power from a power storage and management unit 45 connected to a rechargeable battery 42 and also to an external power source of alternating current (AC) 41, or alternatively a solar cell which may be external or else mounted on the housing of the display 4. A real time clock 43 provides information on the current time to the microprocessor 49, and is powered from the power storage and management circuit 45. The display 4 communicates wirelessly by radio through link 47 with the sensor unit 1; in alternative embodiments, the connection may be through a cable. A buffer unit 46 stores this data obtained by the RF link, indicative of the electricity consumption over a period of time. This information is provided to the microprocessor 49.

A temperature sensor 50 for sensing ambient temperature provides temperature data to the microprocessor 49, and this is used in connection with the requirements for heating and can affect energy consumption levels.

The display unit 4 contains two displays: a graphical screen 44 such as an LCD screen, for displaying text and/or graphical information; and an ambient array 51 controlled by a driver 48. The ambient array 51 is typically one LED (light emitting diode) which indicates the status of the monitoring apparatus, such as whether electricity consumption on the cable is above a predetermined threshold. The display 51 may alternatively be two or more LEDs, for example with different colours. A low power red and green and blue (RGB) light emitting diode is the preferred form of ambient display. The graphical screen display 44 includes areas for displaying information relating to electricity consumption, together with tariff information and energy savings and the like, and can include the logo of the electricity supplier company. The display on the graphical screen can rotate between several modes of operation, in response to user input to the microprocessor 49, for example through buttons or other controls such as a touch pad.

The display 4 preferably also includes a speaker 53 for providing an audio output to the user, indicative of power consumption or other information.

A USB controller 52 provides an interface for the user's PC or router 7 and for power input, if required, to the power storage and management unit 45.

Although not shown in FIG. 3, the memory for the microprocessor 49 may include external memory such as portable, non-volatile memory including flash memory.

The entire system continuously tends towards a state of the lowest possible power consumption. This can be managed by the power storage and management circuit 45 in response to user input. User input into the system, for example through display unit interrogation, increases the system's state of readiness, making the sensor unit 1 more responsive. This is achieved by putting the sensor unit 1 into a state where it seeks commands at reduced intervals.

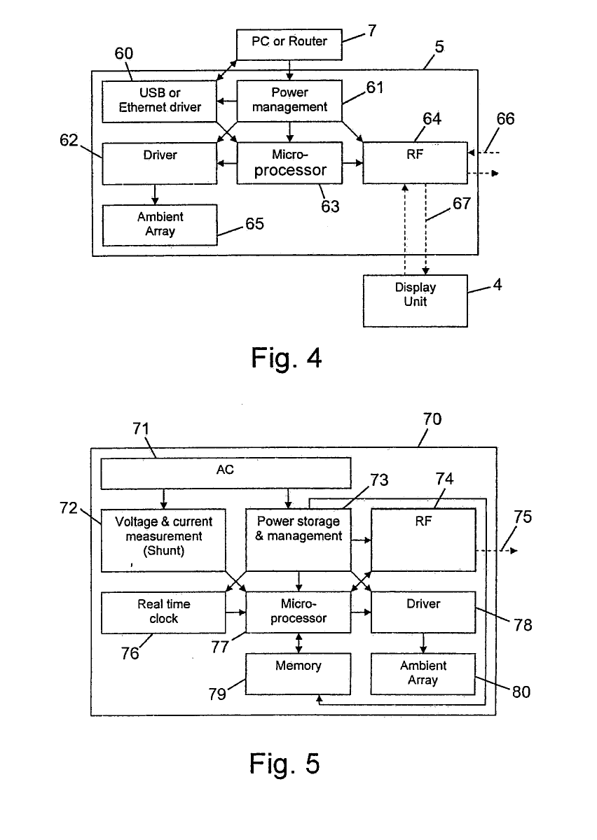

The data return path 5 of FIG. 1 is shown in greater detail in FIG. 4. Consumption data from the electricity sensor 1 is supplied as RF data through link 66 to be stored in the RF buffer 64 accessible by a microprocessor 63. The data return path 5 communicates by wire or wirelessly with the PC or router 7 or with the user display unit 4 through link 67. As with the user display 4, the data return path 5 has its own power management unit 61 and may receive power from an internal rechargeable battery or a solar cell or by other means (not shown). The status of the data return path is indicated by another ambient array 65, such as an LED display operated by a driver 62. The data return path 5 communicates with external data processors or other units through a USB or Ethernet driver 60.

In alternative embodiments, the data return path can include means for accessing the global system for mobile communications (GSM), or Bluetooth or Power Line Communications (PLC) or General Packet Radio Service (GPRS) services, or Public Switched Telephone Networks (PSTN) or other infrastructures which may exist in the domestic or business environment, such as cable or satellite television services and their respective control units.

The monitoring apparatus shown schematically in FIG. 1 may also include one or more individual appliance sensors, alternatively named as “proxy sockets” in some literature. One example is shown in FIG. 5. These individual appliance sensors 70 measure, store and transmit data indicative of the power consumption of the respective appliance, such as a refrigerator or a heater or a television. A wired or wireless data link 75 is provided between an RF buffer unit 74 within the appliance sensor, and other parts of the system which rely on the appliance data, such as the data return path 5 in FIG. 1. The AC supply 71 for the appliance, which may be a wall socket or a cable for example, is fed directly into a voltage and current measurement circuit 72, in series, so that current and voltage may be measured directly and the results fed as data to a microprocessor 77. The power supply 71 is also fed directly to a power storage and management unit 73 for powering the various circuits within the appliance sensor 70. A real time clock 76 provides a time signal to the microprocessor 77 which communicates interactively with an internal memory 79 powered by the power storage and management unit 73. An ambient array 80 may provide a display indicative of the status of the unit, such as whether the current consumption is above a predetermined threshold, and this ambient array 80 may for example be one or more LEDs, optionally with different colours. The ambient array 80 can be driven by a driver 78, communicating with the microprocessor 77.

In alternative embodiments; the appliance sensor 70 has an intelligent switching feature for controlling and managing the power of the respective appliance, for example using data from the resource and cost management application 12. The appliance sensor may be embedded in a plug or in an appliance or in a socket or back box. It may communicate by way of power line communications (PLC), or ELk-485 (formerly RS485), or USB (or USB 2.0) or RS232, or Ethernet, or the like.

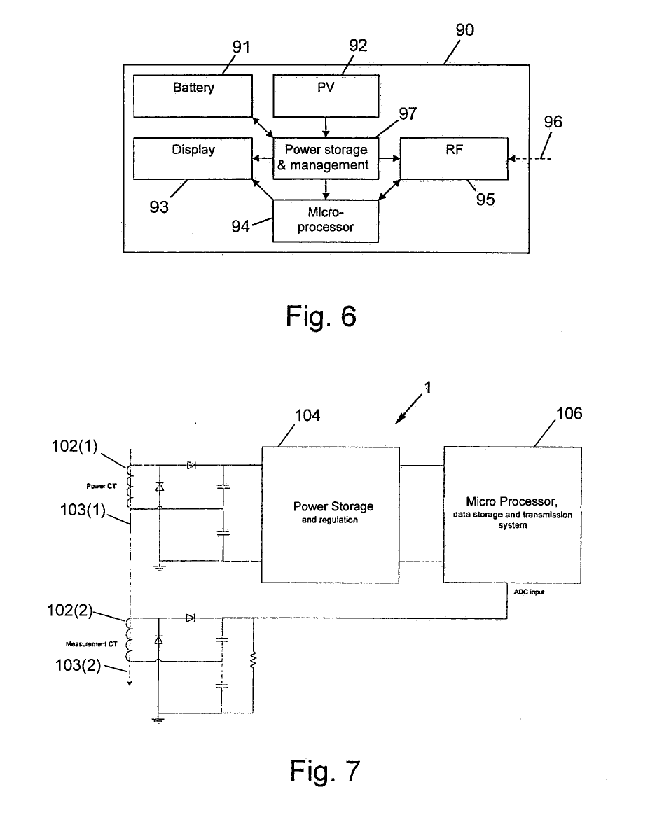

The system of FIG. 1 preferably includes an additional display 90, shown in FIG. 6, referred to as a public display. This is mounted typically on an external wall of a house or business unit, so that it can be viewed by the public. Its purpose is to communicate the energy savings made by the user at those premises.

The public display unit 90 receives RF data from the sensor unit 1 through link 96 and stores them in the RF buffer 95 accessible by the internal microprocessor 94. The public display unit 90 is typically powered by a solar cell 92, i.e. a photovoltaic cell, which supplies a power storage and management unit 97. A rechargeable battery 91 is also provided, corresponding to battery 42 of the user display in FIG. 3. A display unit 93 is driven with data from the microprocessor 94, and provides textual and graphical information of interest to the public, and including the nature of the energy savings for a period of time. It may also include the logo of the electricity supplier, for advertising purposes.

The public display unit 90 is preferably circular and is mounted in a vertical orientation outside the premises. It may have a temperature and light sensor to provide environmental data indicative of ambient temperature and light level, for analysis in the microprocessor 94.

In an alternative system, the display unit 90 may simply indicate whether power is being used by the customer, or whether the monitoring system is being used by the customer, in which case there is no need for the microprocessor 94.

Alternative examples of the sensor unit 1 will now be described with reference to FIGS. 7 to 11. In each of these sensor units 1, the power storage and regulation circuitry 104 includes a rechargeable battery which is required to receive a continuous-trickle charge from a current transformer, and to provide periodic discharge to the microprocessor, data storage and transmission system 106. The most suitable type of battery is the sealed lead acid cell, although it is conceivable that the NiMH battery could be used, as it has a higher energy density. In each example, the current transformer (CT) 102 generates power from the electricity supply cable with which it is coupled, using a clamp, such as to provide maximum mutual inductance with the line. It has a high permeability core 103 that saturates, such as constant voltage charging can be used. The number of turns in the transformer 102 is chosen to set the output voltage for maximum power at a level equivalent to the charging voltage of the battery used. There is no capacitive coupling to the cable, and no electrical contact with it.

Accurate metering of domestic electrical power requires measurement of both current and voltage wave forms of the supply, at a sample rate sufficient to capture all the harmonics carrying significant electrical power. With the use of increasing amounts of low voltage electronic equipment, power may be carried up to the 40th harmonic, necessitating sample rates of the order of kilohertz. However, the power requirements, and the absence of a voltage waveform, in the preferred embodiments of the invention, dictate the need for compromise in the accuracy of the measurements taken. The typical variation in mains supply voltage is 230 volts +10%/−14%, so an assumption of constant voltage will give this order of magnitude of error in the power consumption, which is derived solely from measuring current. Current may be sampled instantaneously, or else by averaging over a sampling period, to produce an integrated charge, measured in Amp hours or Coulombs.

The example shown in FIG. 7 has separate current transformers: a power CT 102(1) and a measurement CT 102(2). The power CT 102(1) provides a trickle charge to the power storage and regulation circuit 104 which drives the microprocessor 106. Current output from the measurement CT 102(2) is instantaneously sampled. The CTs 102(1)-102(2) are preferably made on separate cores 103(1)-103(2), for the best accuracy in measurement, but a single core can be used.

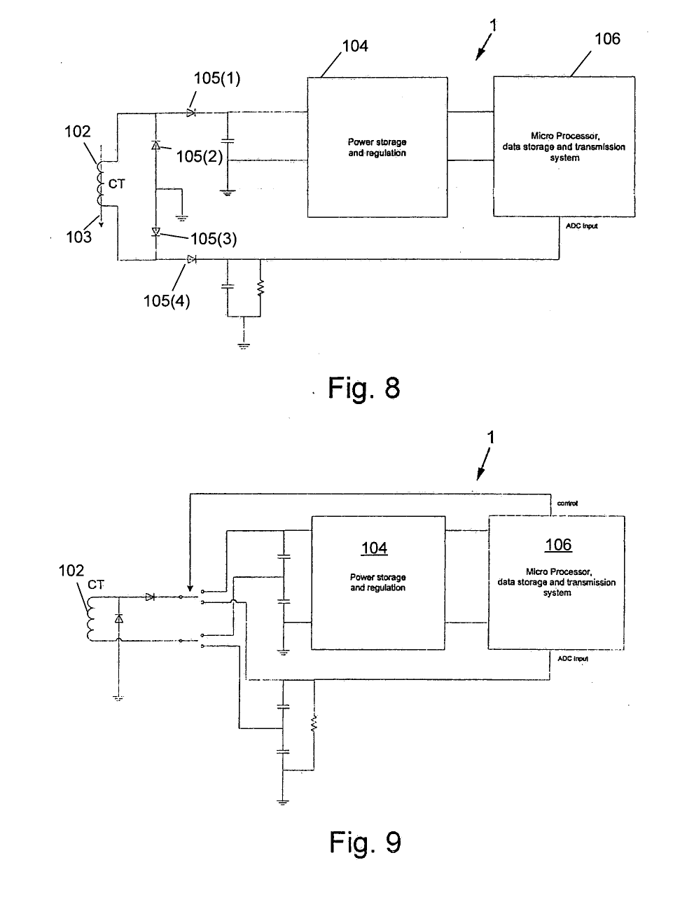

A circuit with just one CT 102 is shown in FIG. 8. This separates this output over two halves of the AC cycle, using rectifying diodes 105(1)-105(4) as shown. This has the benefit of simplicity with only one transformer 102, but the disadvantage of halving the amount of energy available for powering the unit, and the presence of two diode drops.

The alternative circuit shown in FIG. 9 provides time multiplexing between power and measurement. Provided instantaneous samples of the current usage are required, this system can be used. The single CT 102 coil is switched alternately between the power supply circuit 104 and the current measurement circuit 106.

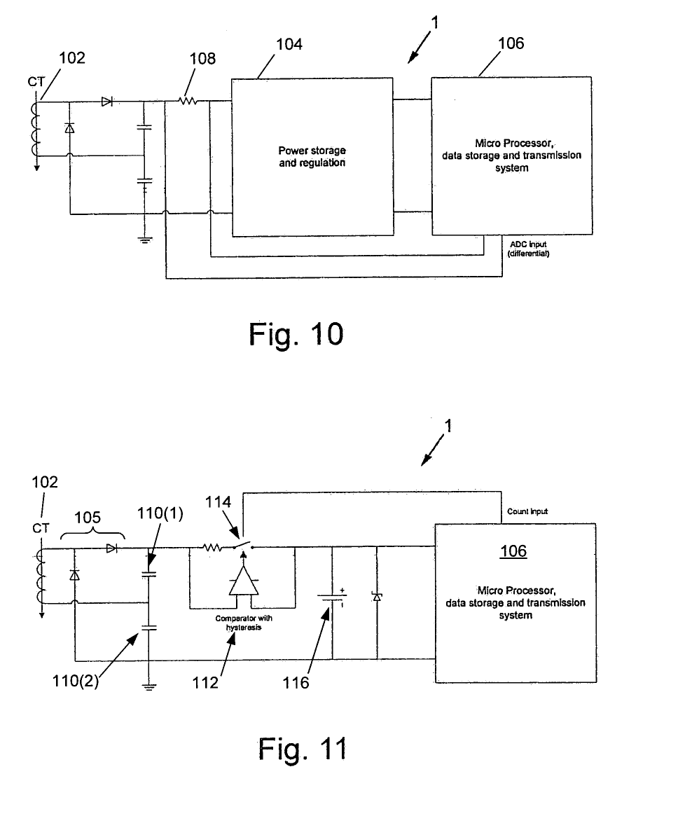

In the further alternative circuit shown in FIG. 10, battery charge current is measured to monitor the line current. Given the assumption that the electrical properties of the rechargeable battery do not change significantly as it is charged, current in the line, i.e. the mains supply cable to which the unit is clamped, may be determined by measuring the current delivered to the battery from the CT 102. The voltage across a shunt resistor 108, in line with the battery charger circuit 104, is sampled by the microprocessor 106 to deduce current. The current delivered to the load 108 at a constant voltage does not vary linearly with the line current, but rather as the square root of the line current. Thus additional computation is required in the microprocessor 106 to derive current from the measured data.

A further example is shown in FIG. 11, which is a metered battery charger. Capacitors 110(1)-110(2) at the output of a rectifier 105 are charged by the CT 102. When they reach a voltage that is a predetermined amount above the battery voltage, a comparator 112 switches the capacitors 110(1)-110(2) to dump charge into the battery 116. Hysteresis is included in the comparator 112 such that the switch 114 is only open again when the voltage across it, and hence the current flowing from the capacitor 110(1) or 110(2) to the battery 116, is O. By assuming that the amount of charge delivered to the battery is equal for each of these cycles, the total charge delivered by the CT can be monitored by counting the number of cycles in the microprocessor 106. The charge delivered can then be used to derive a measurement of line current. Alternative circuits may use more sophisticated step up/down switch mode power supplies.

This circuit shown in FIG. 11 has the advantage of providing an integrated measure of line current, rather than instantaneous samples, and of using a single coil for continuous battery charging and current measurement.

The outputs from the appliance sensors 70 in the system enable the data processors to construct appliance level resource usage patterns, by identifying individual appliances at a system level and allowing deeper analysis of energy usage patterns. The system can infer usage patterns, giving a greater understanding appliance use and mode frequency and hitherto. This level of detail increases the likelihood that a customer will use the system, since it encourages them to collect the richer data and to use the more detailed consumption and energy saving information. Further, the use of the appliance sensors enables intelligent switching of appliances, for control and power management. The system with the appliance sensors builds an energy use profile of individual appliances which can continue to be used even when the appliance sensor has been moved to another appliance. By connecting the voltage and current measurement unit in series with the AC supply, both voltage and current are measured, and this provides an accurate indication of power consumption at the appliance level, data on power consumption from all the appliances in the house can then be accumulated to provide corrections to the integrated consumption data provided by the sensor unit 1, which does not necessarily have the benefit of a voltage measurement.

As was described previously, in a standard energy meter the instantaneous power is derived from measurement of instantaneous current and instantaneous voltage (P=VI). This is then integrated over time to give energy. Both the voltage and current are alternating, e.g., at 50 Hz or 60 Hz, depending on geographical location. Present clamp-on energy monitors measure the current only and assume a fixed voltage amplitude and a fixed phase relationship between current and voltage to estimate the energy usage. Both assumptions lead to inaccuracies in the measured energy.

Embodiments of the present invention can utilize a capacitive measurement of the voltage waveform to deduce the phase relationship between the voltage and the measured current in a clamp on energy meter. This removes the more significant assumption leading to a more accurate energy measurement.

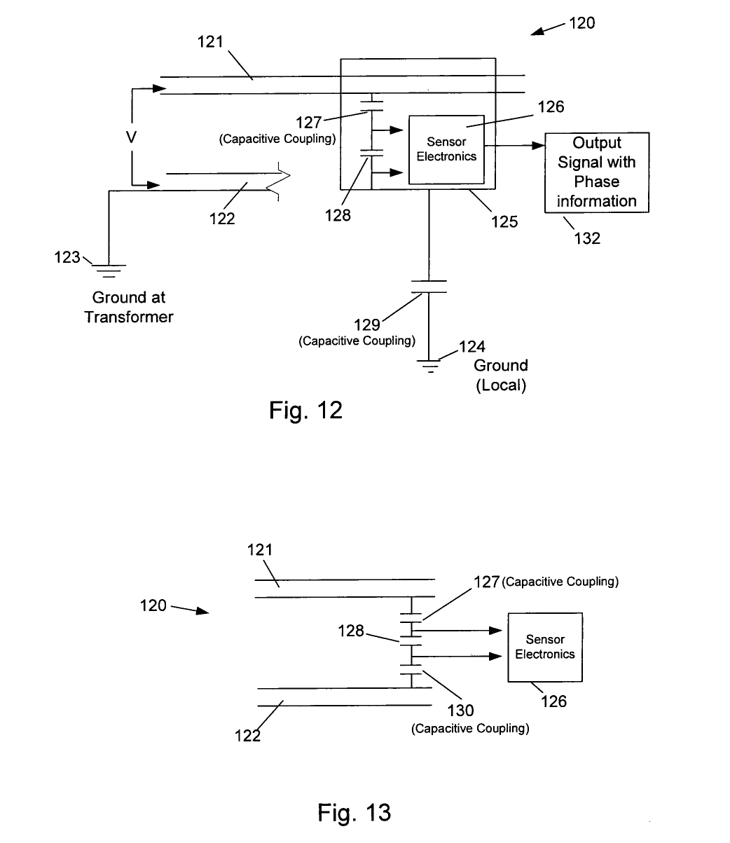

FIG. 12 depicts an embodiment of a capacitive voltage sensor 120 that can be used to measure voltage of a live wire (or line) 121 configured with a neutral wire (or line) 122. The embodiment shown uses a capacitive divider technique to measure the voltage waveform present on the live wire 121. As shown in FIG. 12, a capacitive divider is formed by the capacitance (indicated by capacitor 127) produced by a gap between the live conductor 121 and a sense electrode (this includes the insulation on the live wire 121), a sense capacitance of known value (shown by sense capacitor 128) and the capacitance (shown by capacitor 129) of the device reference voltage to local ground 124. Sensor electronics (voltage measurement circuit) 126 suitable to measure voltage can be connected to or across sense capacitor 128, and can be included within a housing 125. Any suitable voltage measuring electronics/circuitry can be utilized for sensor electronics 126, and one skilled in the art will appreciate that the invention is not limited to any particular configuration of such. The sensor electronic can include analog-to-digital conversion circuitry/components. In exemplary embodiments, the housing 125 can be implemented with clamp-on functionality for placement adjacent a wire, e.g., live wire 121, as shown.

The sense capacitor 128 (which can be disposed in the electrically insulative housing 125) is of known capacitance, and is electrically connected/coupled to the sense electrode (shown by 127). The sense capacitor 128 is, without direct physical connection (e.g., not directly connected by any electrical conductors/materials), capacitively coupled to a local ground 124; thus, facilitating ease of use and/or coupling to the power line(s). In exemplary embodiments, the capacitive coupling (shown by 129) of the sensor 120 or sense capacitor 128 to local ground 124 may be formed, e.g., by a portion of the connected sensor electronics or voltage measurement circuit 126 and the local ground 124; or, a second sense electrode (connected to circuit 126 or capacitor 128) and the local ground 124.

The voltage measurement circuit, e.g., shown by sensor electronics 126, are connected to the sense capacitor 128 and responsive to voltage produced across the sense capacitor 128 and function to provide an output signal 132 the phase of which is representative of the phase of the voltage V on the cable 121. The output signal 132 can be used by the sensor 120 itself, e.g., for power calculations and display readings, or sent to other apparatus or locations for use.

The voltage across the sense capacitance, e.g., capacitor 128, as measured is proportional to the voltage V on the live wire 121 (shown relative to a ground 123 at transformer), but due to the unknown and possibly varying capacitances 129 to the live wire 121 and the local ground 124 the ratio is unknown. Therefore, the voltage across the sense capacitor 128 gives information about the phase of the live wire voltage V, but not about amplitude. Assumptions or a priori values of the amplitude can be utilized in conjunction with such phase measurement/determination.

As the amplitude of the measured voltage V is dependent upon the ratio of capacitances in the system (e.g., the capacitive coupling between the sense capacitor 128 and live power line 121, the sense capacitor itself 128, and the capacitive coupling between the sense capacitor and local ground 129), variations in the capacitive coupling to local ground 129 can cause considerable variations in measurements. For example, someone walking near the sensor can change the capacitance to local ground by a factor of 2 thereby causing a change in the amplitude of the signal by a factor of 2.

In order to cope (or better cope) with the varying nature of the unknown capacitance (e.g., shown by 129) between the local ground 124 and the measurement system (including sense capacitor), some filtering of the sensed voltage waveform can be useful. In exemplary embodiments of a capacitive voltage sensor according to the invention, the voltage waveform can be filtered to give the fundamental of the supply voltage (e.g., 50 Hz or 60 Hz), which can reduce or eliminate effects of changes in capacitances within one cycle. A suitable filter, e.g., a Butterworth filter or Chebyshev passband filter, can be utilized for and implemented with the sensor for such filtering.

For such filtering mentioned above, a suitable filter can be included or implemented with the sensor 120, e.g., connected to the sense capacitor 128 or otherwise included in or implemented with the sensor electronic (voltage measurement circuit) 126, and be configured and arranged to pass the fundamental of the supply voltage measured from the cable and produce a filtered output signal. As described previously, typical frequencies for utility-supplied power are 50 Hz and 60 Hz. The filter can be designed based on the anticipated or known frequency of delivered power. The voltage measurement circuit 126 or filter itself can be configured and arranged to average the filtered output signal over a time period; also, it is possible to perform time averaging of the measured signal first, prior to filtering.

The filtering and time averaging can be such that the relevant time periods are faster than the natural variations in the frequency of the supplied power of the power line but slow enough to filter or mitigate noise in the voltage measurement. In exemplary embodiments, the time period for averaging can range from about 0.1 second to about 1.0 second, though other time periods may of course be utilized/implanted.

The voltage waveform (including measured/calculated phase information) used in the power calculation can accordingly be reconstructed using the known phase relationship between measured current and sensed voltage waveform (e.g., as derived from sensor 120) and an assumed amplitude (e.g., 230 V_{RMS}).

FIG. 13 is a schematic circuit diagram of a further embodiment of a capacitive voltage sensor 120 in accordance with present invention. The unknown capacitance (e.g., capacitance 129 of FIG. 12) to local ground 124 can be replaced (or supplemented) with a known (or estimated, e.g., from prior knowledge or empirical data) higher capacitance (shown by capacitor 130) to the neutral wire 122 to improve the stability of the waveform measurement, as shown in FIG. 13. The capacitance 130 can be formed alone from the capacitive coupling (e.g., including wire insulation) to the neutral line/wire 122, or can include a second sense capacitor, similar to sense capacitor 129. An additional or secondary clamp-on connection can be utilized for connection to the neutral line 122 for such coupling. Such an additional or secondary clamp-on connection can be included within or connect to the housing of the first clamp-on connection or a separate, secondary housing.

Capacitive voltage sensors such as shown and described for FIGS. 12 and 13 can provide measurement of voltage-to-current phase relationship to improve accuracy of energy measurement. Voltage measurement can involve direct interaction only with one (e.g., live) wire. Further, such measurement can be independent of clamping capacitance (e.g., capacitor size, insulation material, insulation thickness, etc.). Moreover, there is no direct connection required to the live wire, which allows installation by untrained users.

Such capacitive voltage sensors can provide improved accuracy over existing clamp-on energy monitors. These capacitive voltage sensors according to the present invention can be lower in cost relative to the prior art, due to a single-device structure. Additionally, such capacitive sensors can be immune to inaccurate fitting and variation in an installation site.

One skilled in the art will appreciate that the capacitive voltage sensors shown and described for FIGS. 12-13 can be utilized alone, or they may be used in combination with other embodiments of the present invention, e.g., as shown and described for FIGS. 1-11.

Additionally, it will be appreciated that the invention is not limited to the examples shown here. Other methods of communication and of display can be used, and the data processing within the entire system can be located at any convenient point, whether by the meter or in another unit such as a display, or elsewhere using the Internet. It will be understood that this system, in its preferred embodiment, is particularly reliable with minimum maintenance, through the use of electrical power from the mains power supply itself and/or from rechargeable batteries or solar cells. Consumption data are stored reliably in memory which is protected from tampering or damage, and from confusion with any data relating to other consumers. The sensor unit is intended to be fitted just once and to last for several years without the need for maintenance. The use of communications networks allows the software in the system to be updated from time to time without direct intervention.

1. Apparatus for monitoring the voltage of electricity supplied on a cable, comprising:
a sense electrode sensor unit housed in an electrically-insulative housing and configured and arranged to form a capacitive coupling between the sense electrode and the cable;
a sense capacitor disposed in the housing and of known capacitance, wherein the sense capacitor is electrically coupled to the sense electrode and, without direct physical connection, capacitively coupled to a local ground; and
a voltage measurement circuit connected to the sense capacitor and responsive to voltage produced across the sense capacitor to provide an output signal the phase of which is representative of the phase of the voltage on the cable.

2. Apparatus according to claim 1, wherein a capacitive coupling between the sense capacitor and the local ground is formed by a ground plane of the voltage measurement circuit and the local ground.

3. Apparatus according to claim 1, further comprising a second sense electrode connected to the voltage measurement circuit, wherein a capacitive coupling between the sense capacitor and the local ground is formed by the second sense electrode and the local ground.

4. Apparatus according to claim 1, further comprising a filter connected to the sense capacitor and configured and arranged to pass the fundamental of the supply voltage measured from the cable and produce a filtered output signal.

5. Apparatus according to claim 1, wherein the voltage measurement circuit is configured and arranged to average the filtered output signal over a time period.

6. Apparatus according to claim 5, wherein the time period is from about 0.1 second to about 1.0 second.

7. Apparatus according to claim 1, further comprising a data communication circuit powered from a power supply circuit and responsive to the output signal to transmit data representative of the output signal to an external receiver.

8. Apparatus according to claim 7, further comprising a power supply configured and arranged to supply power to the data communication circuit.

9. Apparatus according to claim 1, wherein the housing is clampable over the cable.

10. Apparatus according to claim 1, further comprising a user display unit having an electrically-insulative housing, separate from the sensor but in wired or wireless communication with the sensor to display information relating to a line voltage derived from the output signal.

11. Apparatus according to claim 10, in which the display unit comprises a rechargeable internal battery.

12. Apparatus according to claim 11, in which the display unit comprises a solar power panel arranged to power the display unit and/or to recharge the internal battery.

13. Apparatus according to claim 10, in which the display unit comprises a display screen and a data processor arranged to display text and/or graphics on the screen relating to the consumption of electricity.

14. Apparatus according to claim 10, in which the display unit comprises a light-emitting display and a driver for controlling that display to indicate the status of the apparatus.

15. Apparatus according to claim 14, in which the light-emitting display comprises ail array of coloured LEDs.

16. Apparatus according to claim 1, in which the voltage measurement circuit includes a means for storing electrical energy.

17. Apparatus according to claim 16, wherein the means for storing electrical energy comprises is a rechargeable battery.

18. Apparatus according to claim 1, further comprising a public display unit, separate from the sensor unit and from any user display unit, but in wired or wireless communication with the sensor unit to display information relating to the consumption of electricity including information derived from the output signal.

19. Apparatus according to claim 1, comprising a computer network interconnecting the sensor unit with other data processing units for communicating with the user and/or the supplier of the electricity.

20. Apparatus according to claim 19, in which the computer network is connected to the Internet.

21. Apparatus according to claim 20, in which the computer network comprises a data processor configured for customer relationship management between the user and the supplier of the electricity.

22. Apparatus according to claim 1, further comprising a secondary sense capacitor configured and arranged to be connected to a neutral wire operational with the cable.

23. Apparatus according to claim 22, further comprising a housing portion configured and arranged to form a secondary clamp-on connection with a neutral line associated with the cable.

24. Apparatus according to claim 23, wherein the secondary clamp-on connection is included in a second housing.

25. Apparatus for monitoring the voltage of electricity supplied on a cable, comprising:
a sense electrode sensor unit housed in an electrically-insulative housing and configured and arranged to form a capacitive coupling between the sense electrode and the cable;
a sense capacitor disposed in the housing and of known capacitance, wherein the sense capacitor is electrically coupled to the sense electrode and, without direct physical connection, capacitively coupled to a neutral line associated with a live line of the cable; and
a voltage measurement circuit connected to the sense capacitor and responsive to voltage produced across the sense capacitor to provide an output signal the phase of which is representative of the phase of the voltage on the cable.

26. Apparatus according to claim 25, further comprising a filter connected to the sense capacitor and configured and arranged to pass the fundamental of the supply voltage measured from the cable and produce a filtered output signal.

27. Apparatus according to claim 25, wherein the voltage measurement circuit is configured and arranged to average the filtered output signal over a time period.

28. Apparatus according to claim 27, wherein the time period is from about 0.1 second to about 1.0 second.
